(19) United States
(12) Patent Application Publication
(10) Pub. No.: US 2006/0215191 A1
(43) Pub. Date: Sep. 28, 2006

(54) Display apparatus

(75) Inventors: Susumu Tanase, Osaka (JP); Atsuhiro Yamashita, Osaka (JP); Masutaka Inoue, Osaka (JP); Yukio Mori, Osaka (JP)

Correspondence Address: NDQ&M WATCHSTONE LLP, 1300 EYE STREET, NW, 400 EAST TOWER, WASHINGTON, DC, 20005, US

(73) Assignee: Sanyo Electric Co., Ltd., Moriguchi-shi (JP)

(21) Appl. No.: 11/385,684

(22) Filed: Mar. 22, 2006

(30) Foreign Application Priority Data
Mar. 22, 2005 (JP) JP2005-081000

(51) Int. Cl. H04N 1/60; G03F 3/08

(52) U.S. Cl. 358/1.9; 358/518; 382/167

(57) ABSTRACT

A display apparatus includes an RGB-RGBX signal converter configured to convert digital R, G, and B input signals into digital R, G, B, and X input signals. A D/A converter is configured to convert the digital R, G, B, and X input signals into analog R, G, B, and X output signals. An RGBX type self light-emitting display is configured to receive the analog R, G, B, and X output signals. A calculator is configured to calculate an accumulated power consumption value of the self light-emitting display for each screcn, based on the digital R, G, B, and X input signals. A controller is configured to control amplitudes of the respective analog R, G, B, and X input signals by controlling a reference voltage supplied to the D/A converter based on the accumulated power consumption value, and to supply the respective amplitudeaontrolled analog R, G, B, and X input signals to the self light-emitting display.

### CROSS REFERENCE TO RELATED APPLICATION

This application is based upon and claims the benefit of priority from prior Japanese Patent Application P2005-081000 filed on Mar. 22, 2005; the entire contents of which are incorporated by reference herein.

### BACKGROUND OF THE INVENTION

1. Field of the Invention

The present invention relates to a display apparatus including a self light-emitting display, such as an organic electroluminesce (EL) display, an inorganic EL display, or a plasma display. In particular, the present invention relates to a display apparatus including a self light-emitting display based on R, G, B, and X (X is an arbitrary color other than R, G, and B).

2. Description of the Related Art

Self light-emitting displays such as an organic EL display are characterized in the thin thickness, light weight, and low power consumption and the like and are used for an increasing number of applications. nowever, in applications for a cellular phone, a digital still camera or the like, these displays have been required to provide flrther lower power consumption.

A red (hereinafter referred to as a symbol “R”), a green (hereinafter referred to as a symbol “G”), and a blue (hereinafter referred to as a symbol “B”) type organic EL display in which white (hereinafter referred to as a symbol “W”) luminescence material is attached with color filters of RGB has been already developed. The RGB type organic EL display includes organic EL elements for the respective R, G, and B unit pixels. In the RGB type organic EL display, when light passes through a color filter, a part of the light is absorbed by the color filter, thus deteriorating the light use efficiency. This low light use efficiency suppresses the power consumption from being decreased.

In view of the above, the present applicant has already developed a signal processor of an organic EL display. The signal processor is the one of an RGBW type organic EL display (self light-emitting display) in which one pixel is composed of four unit pixels of R, G, B, and W and the R, G, and B unit pixels include color filters and the W unit pixel does not include a color filter. The signal processor can reduce the power consumption The RGBW type organic EL display includes organic EL elements for the respective R, G, B, and W unit pixels.

By the way, in self light-emitting displays such as an organic EL display, large current flows in an emission element (organic EL element) when an image through which the entire screen is bright is displayed. When large current flows in the emission element (organic EL element), the power consumption is increased. Furthermore, continuous flow of large current in the emission element (organic EL element) arcclerates the deterioration of the performance.

According to Japanese Patent Unexamined Publication No. 2003-255901, a method has been already developed in which, in an RGB type organic EL display, an accumulated luminance value of input video signals is calculated for each one screen to control the amplitude of an input video signal so that the input video signal has a smaller amplitude as the calculated luminance accumulation value is higher.

According to Japanese Patent Unexamined Publication No. 2003-280589, another method bas been already developed in which, in an RGB type organic EL display, accumulated input signal values for R, G, and B are calculated for each one screen and the resultant values arc multiplied with a weighting factor in proportion with a temporal degradation rate of emission elements corresponding to the respective R, G, and B input signal accumulation values to add the resultant values to the multiplication results of R, G, and B, thereby calculating R, G, and B weighted addition values on the basis of one screen. Thus, the amplitude of an input video signal is controlled so that the input video signal has a smaller amplitude as the resultant RGB weighted addition value is higher.

In view of the above, an RGBW type organic EL display has significantly different emission efficiencies of the respective R G, B, and W emission elements. Thus, the total sum of accumulation values of the respective R, G, B, and W input signals of on the basis of one screen is not proportional to the current consumption of the organic EL display. Thus, even when the amplitude of the input video signal is controlled based on the total sum of the accumulation values of the respective R, G, B, and W input signals on the basis of one screen, optimal low power consumption cannot be realized.

### SUMMARY OF THE INVENTION

The present invention realizes optimal low power consumption in a display apparatus including an RGBX (symbol “W” refers to an arbitrary color other than R, G, and B) type self light-emitting display.

A aspect of the present invention inheres in a display apparatus encompassing, an RGB-RGBX signal converter configured to convert digital R, G, and B input signals into digital R, G, B, and X input signals, a D/A converter configured to convert the digital R, G, B, and X input signals into analog R, G, B, and X output signals, an RGBX type self light-emittng display configured to receive the analog R, G, B, and X output signals, a calculator configured to calculate an accumulated power consumption value of the self light-mitting display for each screen, based on the digital R, G, B, and X input signals, and a controller configured to control amplitudes of the respective analog R, G, B, and X input signals by controlling a reference voltage supplied to the D/A converter based on the accumulated power consumption value, and to supply the respective amplitude-controlled analog R, G, B, and X input signals to the self light-mitting display.

In the display apparatus according to the aspect of the present invention, the calculator may include a plurality of multipliers that are provided for the respective digital R, G, B, and X input signals and that multiply, for each one pixel, the respective digital R, G, B, and X input signals with a coefficient depending on current consumption for unicolor display by respective R, G, B, and X unit pixels, and a power consumption accumulator configured to calculate, for each one screen, a total sum of accumulation values for one screen of the multiplication result of the respective multipliers or an accumulation value for one screen of the total sum for each one pixel of the multiplication result of the respective multipliers as the accumulated power consumption value.

In the display apparatus according to the aspect of the present invention, the controller may control the reference voltage so that the respective analog R, G, B, and X input signals become small amplitudes when the accumulated power consumption value is higher than a fixed value.

In the display apparatus according to the aspect of the present invention, the reference voltage may include a black-side reference voltage for defining emission luminances to black levels of the respective digital R, G, B, and X input signals and a white-side reference voltage for defining emission luminances to white levels of the respective R, G, B, and X input signals, and the controller may control the white-side reference voltage based on the accumulated power consumption value.

### BRIEF DESCRIPTION OF THE DRAWINGS

FIG. 1 is a schematic diagram showing an arrangement of a pixel including four units of RGBW.

FIG. 2 is a block diagram showing an arrangement of a display apparatus.

FIG. 3 is a schematic diagram showing an example of an RGB signal.

FIG. 4 is a schematic diagram showing a min(RGB).

FIG. 5 is a schematic diagram showing “input signal—min(RGB)”.

FIG. 6 is a schematic diagram showing an RGBW signal ratio for representing Wₜ(255).

FIG. 7 is a schematic diagram showing an RGBW signal ratio for representing Wₜ(100).

FIG. 8 is a schematic diagran showing an RGBW value calculated by adding the RGB value of FIG. 5 and the RGB value of FIG. 7.

FIG. 9 is a flow chart showing a panel controlling procedure.

FIG. 10 is a schematic diagram showing chromaticity coordinates (x_{R}, y_{R}), (x_{G}, y_{G}), (x_{B}, y_{B}), and (x_{W}, y_{W}) of RGBW and chromaticity coordinates (x_{Wt}, y_{Wt}) of target white Wₜ.

FIG. 11 is a flow chart showing a signal conversion procedure for converting an RGB signal into an RGBW signal.

FIG. 12 is a flow chart showing another example of signal conversion procedure for converting an RGB signal into an RGBW signal.

FIG. 13 is a schematic diagram showing an example of an RGB signal.

FIG. 14 is a schematic diagram showing “RGB signal—min(RGB)”.

FIG. 15 is a schematic diagram showing a min(RGB).

FIG. 16 is a schematic diagram showing an RGBW signal corresponding to min(RGB).

FIG. 17 is a schematic diagram showing an RGBW value calculated by adding the RGB value of FIG. 14 and the RGBW value of FIG. 16.

FIG. 18 is a schematic diagram showing an R₁G₁B₁W₁ input signal obtained from RGBW signal.

FIG. 19 is a schematic diagram showing an R₁G₁B₁ input signal—min(R₁G₁B₁).

FIG. 20 is a schematic diagram showing a min(R₁G₁B₁).

FIG. 21 is a schematic diagram showing an RGBW signal corresponding to a min(R₁G₁B₁).

FIG. 22 is a schematic diagram showing an RGBW value calculated by adding the R₁G₁B₁ value of FIG. 19 and the R₁G₁B₁W₁ value of FIG. 21.

FIG. 23 is a flow chart showing still another example of a signal conversion procedure for converting an RGB signal into an RGBW signal.

FIG. 24 is a block diagram showing an arrangement of a display apparatus including an RGBW type self light-emitting display.

FIG. 25 is a graph showing an input-output characteristic of a gain calculator.

FIG. 26 is a circuit diagram showing a reference voltage adjustor for R.

FIG. 27 is a graph showing an input-utput characteristic of a DAC.

### DETAILED DESCRIPTION OF THE JNTON

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### COMPARATIVE EXAMPLE

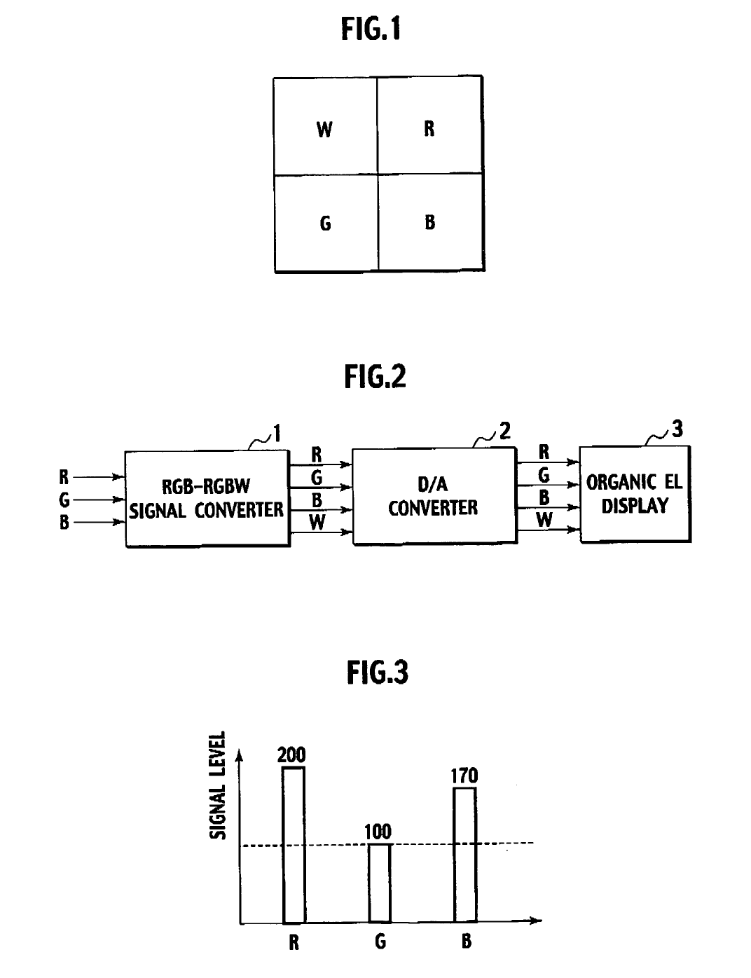

The following section will describe a signal processor of the RGBW type self light-enitting display developed by the present applicant. The signal processor of the RGBW type self light-cmitting display developed by the present applicant may be used for a self light-emitting display (e.g., organic EL display) in which white luminescence material is attached with a color filter. As shown in FIG. 1, the self light-emitting display is provided so that one pixel is composed of four unit pixels among which three unit pixels include color filters for displaying three primary colors (e.g., R, G, and B). The remaining one unit pixel does not include a color filter and is exclusively used for displaying W.

In the RGBW arrangement as described above, a unit pixel exclusively used for displaying white docs not include a color filter and thus has a very high light use efficiency. Significant low power consumption can be realized when white 100% is displayed by causing the exclusive unit pixel for displaying white to emit light to display white 100% instead of causing the unit pixels for displaying R, G, and B to emit light to display white 100%, for instance.

However, in an actual case, white obtained by the white luminescence material has a chromaticity that is frequently different from a chromaticity of target white Therefore, it is required to add the light emission of the RGB unit pixels to the exclusive unit pixel for displaying white.

Thus, a signal processing method developed by which, when white obtained by a white luminescence material has a chromaticity different from the chromaticity of target white, then RGB input signals are converted to RGBW signals that correspond to the input signals, that have the same luminance and chromaticity, and that can reduce the power consumption.

[1] Arangement of Display Apparatus

FIG. 2 shows an arrangement of a display apparatus.

An RGB-RGBW signal converter 1 receives a digital RGB input signal. The RGB-RGBW signal converter 1 converts an RGB input signal to an RGBW signal. The RGBW signal obtained by the RGB-RGBW signal converter 1 is converted to an analog RGOW signal by a digital to analog (D/A) converter 2. The RGBW signal obtained by the D/A converter 2 is sent to an organic EL display 3 in which one pixel is composed of four RGBW unit pixels.

[2] Basic Concept of RGB-RGBW Signal Conversion

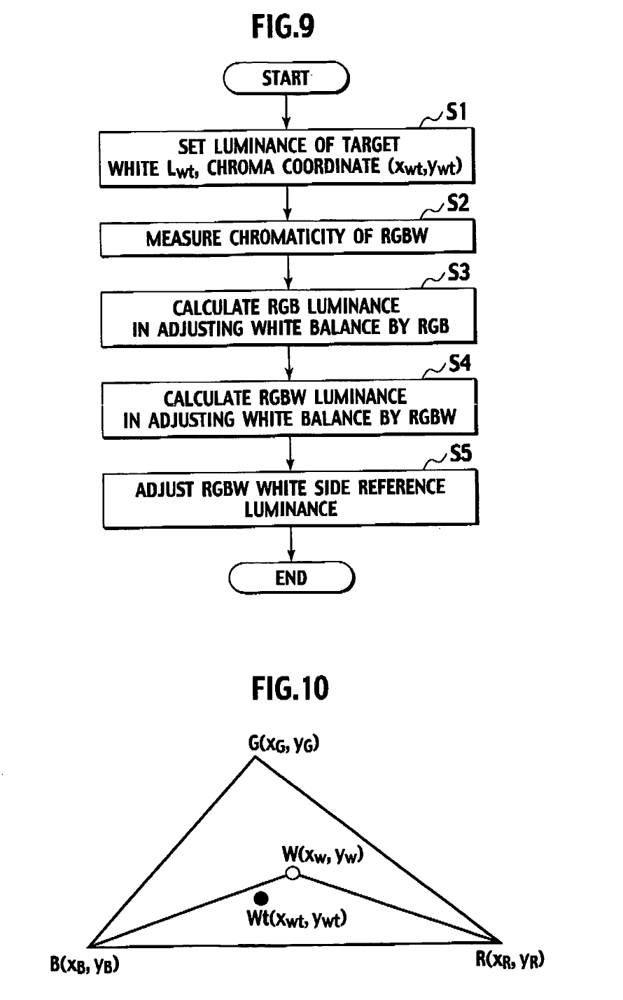

This exemplary embodiment assumes R, G, aind B input signals as shown in FIG. 3. For convenience of description, the R, G, and B input signals are not previously subjected to gamma correction. It is also assumed that, such RGB luminance that realizes target white luminance and chromaticity based on only R, G, and B is previously set as a white-side reference luminance (white-side reference voltage to RGB of D/A converter 2). It is noted that the white-side reference luminance of W is adjusted so that a target luminance (W luminance dctcrmincd by step S4 of FIG. 9) (which will be described later)) is reached when only W is displayed.

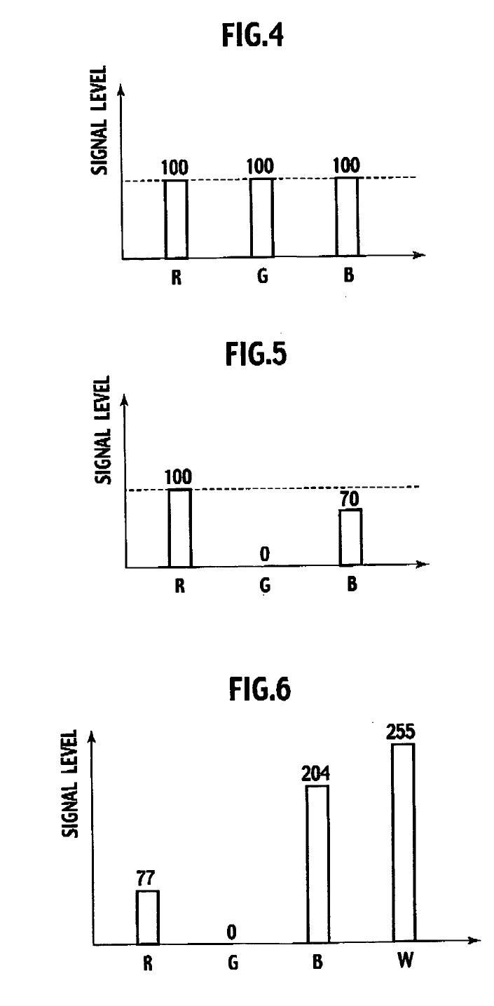

In this example, the RGB input signal value is represented by eight bits and R=200, G=100, and B=170. The minimum value of the RGB input signal value is 100. The RGB input signal value is separated, as shown in FIG. 4, to the minimum values (min(RCTB)) and the other values (input signal—min(RGB)) as shown in FIG. 5. In the case of FIG. 4, when all of the RGB input signal values are 100, they are equivalent to a target white Wₜ(100).

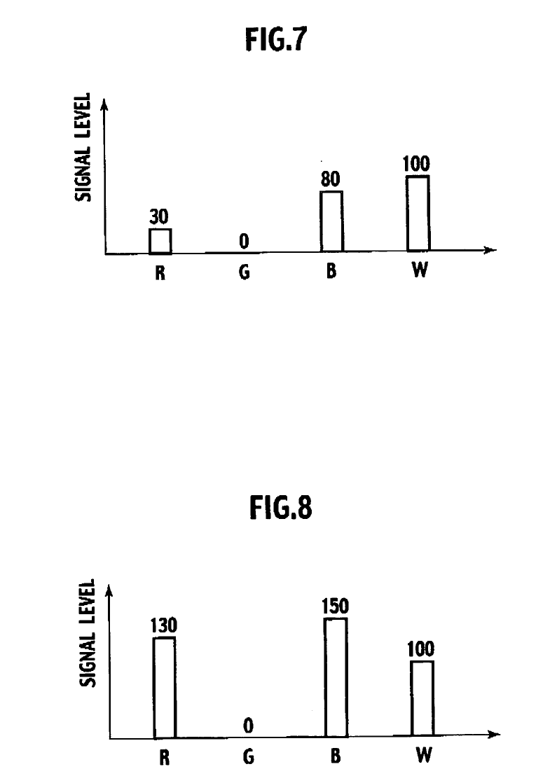

For example, when assuming that the R, G, B, and W signal values arc signal values as shown in FIG. 6 (77, 0, 204, and 255) in order to express target white Wₜ (255) when the R, G, and B input signal values are all 255, the R, G, B, and W input signal values in order to realize target white Wₜ(100) when the R, G, and B input signal values are all 100 are as shown in FIG. 7.

The signal values as shown in FIG. 6 can be calculated based on R, G, and B luminance values and R, G, B, and W luminance values in order to realize the target white It is assumed that R, G, B, and W signal values in order to realize target white when the R, G, and B input signal values are all 255 are R1, G1, B1, and W1. When assug that R, G, and B luminance values in order to realize target white luminance and chromaticity are LR1, LG1, and LB1 and RGB, and W luminance values in order to realize target white luminance and chromaticity are LR2, LG2, LB2, and LW2, then RGB, and W signal values in order to realize the target white when R, G, and B input signal values are all 255 arc: R1=255×LR2/TR1, G1=255×LG2/LG1, B1=255×LB2/LB1, and W₁=255. In particula, W can be defmed only by an RGBW display system and thus the unique results of 255 are obtained. A method for calculating RGB luminance value and RGBW luminance value in order to realize target white lumiinance and chromaticity will be described later.

The values of R, G, B, and W in FIG. 7 are calculated by the following formula (1).
R=77×100/255=30
G=0×100/255=0
B=204×1.00/255=80
W=255×100/255=100 (1)

Here, the R, G, and B values of FIG. 4 are substituted with the R, G, and B values of FIG. 7. The R, G, and B values shown in FIG. 3 are converted into the R, G, and B values shown in FIG. 8 by adding the R, G, and B values of FIG. 5 to the R, G, and B values of FIG. 7.

The values of R, G, B, and W of FIG. 8 are calculated by the following formula (2).
R=100+30=130
G=0+00
B=70+80=150
W=0+100=100 (2)

The white-side reference luminances of R, G, and B (R, G, and B luminance values in order to realize luIminance and chromalicity of target white), RGBW luminance value in order to realize the luminance and chromaticity of the target white, and RGBW signal value in order to realize the target white when R, G, and B input signal values are all 255 are previously calculated by a panel adjustment processing.

[3] First RGB-RGBW Signal Conversion Processing

FlG. 9 shows a procedure of the panel adjustment processing.

First, a luminance L_{wt} and chromaticity coordinates (x_{wt}, y_{wt}) of a target white Wₜ are set (step S1).

Next, the RGBW chromaticity of the organic EL display 3 is measured (step S2) When the R chromaticity is measured for example, only unit pixels for displaying R of the organic EL display 3 are caused to emit light and the chromaticity is measured by an optical measurement device. Chromaticity coordinates of the measured RGBW are assumed as (x_{R}, y_{R}), (x_{G}, y_{G}), (x_{B}, y_{B}), and (x_{W}, y_{W}), respectively.

Next, R, G, and B luminance values when adjusting white balance (WB) by R, G, and B are calculated (step S3). Specifically, this step calculates, based on the three colors of R, G, and B, a luminance value L_{R} (which corresponds to the above LR1), a luminance value L_{G} (which corresponds to the above LG1), and a luminance value L_{B} (which corresponds to the above LB1) of the R, G, and B in order to express the luminance L_{wt} and the chromaticity (x_{wt}, y_{wt}) of the target white Wₜ. The luminance values L_{R}, L_{G}, and L_{B} arc calculated based on the following formula (3).

$$( \begin{matrix}\frac{{x}_{R}}{{y}_{R}} & \frac{{x}_{G}}{{y}_{G}} & \frac{{x}_{B}}{{y}_{B}} \\ 1.0 & 1.0 & 1.0 \\ \frac{{z}_{R}}{{y}_{R}} & \frac{{z}_{G}}{{y}_{G}} & \frac{{z}_{B}}{{y}_{B}}\end{matrix} ) ( \begin{matrix}{L}_{R} \\ {L}_{G} \\ {L}_{B}\end{matrix} ) = ( \begin{matrix}\frac{{x}_{wt}}{{y}_{wt}} {L}_{wt} \\ {L}_{wt} \\ \frac{{z}_{wt}}{{y}_{wt}} {L}_{wt}\end{matrix} ) \qquad ( 3 )$$

In the formula (3), z_{R}=1−x_{R}−y_{R}, z_{G}=1−x_{G}−y_{G}, z_{B}=1−x_{B}−y_{B}, and z_{wt}=1−x_{wt}, y_{wt}.

Next, the R, G, B, and W luminance values for the adjustment of white balance (WB) by RGBW are calculated (step S4). Specifically, based on the four colors of RGBW, this step calculates luminance values L_{R} (which corresponds to the above LR2), L_{G} (which corresponds to the above LG2), L_{B} (which corresponds to the above LB2), and L_{W} (which corresponds to the above LW2) of RGBW in order to express the luminance L_{wt} and the chromaticity (x_{wt}, y_{wt}) of the target white Wₜ.

When assuming that a relation between the RGB, and W chromaticity coordinates (x_{R}, y_{R}), (x_{G}, y_{G}), (x_{B}, y_{B}), and (x_{W}, y_{W}) and the target white Wₜ chromaticity coordinate (x_{wt}, y_{wt}) is the one as shown in FIG. 10, the chromaticity of the target white Wₜ can be represented by only the three colors of R, B, and W. Based on the three colors of R, B, and W, the R, B, W luminance values L_{R} (which corresponds to the above LR2), L_{B} (which corresponds to the above LB2), and L_{W} (which corresponds to the above LW2) in order to express the luminance L_{W} and chromaticity (x_{wt}, y_{wt}) of the target white Wₜ are calculated based on the following formula (4). In this case, L_{G} corresponding to the above LG2 is zero.

$$( \begin{matrix}\frac{{x}_{R}}{{y}_{R}} & \frac{{x}_{w}}{{y}_{w}} & \frac{{x}_{B}}{{y}_{B}} \\ 1.0 & 1.0 & 1.0 \\ \frac{{z}_{R}}{{y}_{R}} & \frac{{z}_{w}}{{y}_{w}} & \frac{{z}_{B}}{{y}_{B}}\end{matrix} ) ( \begin{matrix}{L}_{R} \\ {L}_{w} \\ {L}_{B}\end{matrix} ) = ( \begin{matrix}\frac{{x}_{wt}}{{y}_{wt}} {L}_{wt} \\ {L}_{wt} \\ \frac{{z}_{wt}}{{y}_{wt}} {L}_{wt}\end{matrix} ) \qquad ( 4 )$$

In the formula (4),z_{R}=1−x_{R}−y_{R}, z_{W}=1−x_{W}−yW, z_{B}=1−x_{B}−y_{B}, and z_{wt}=1−x_{wt}, y_{wt}.

Next, the calculation result of the above step S3 is used to calculate RGBW white-side reference luminance (step S5).

When the RGB input signal value is represented by eight bits, the RGB white-side reference luminance is adjusted so that, when an RGB signal of (255, 255, 255) is supplied, the emission luminance and the emission color are the luminance L_{wt} and the chromnaticity (x_{wt}, y_{wt}) of the target white Wₜ. Specifically, when the RGB signal of (255, 255, 255) is supplied, the RGB white-side reference luminance is adjusted so that the R, G, and B luminances are the luminance value L_{R}, L_{G}, and L_{B} calculated by the above step S3, respectively When the RGB wbite-side reference luminance is adjusted as described above and when the input R, G, and B signals have an identical value, the emitted color always has the chrornaticity of the target white. It is noted that the W white-side reference luminance is adjusted so that the W white-side reference luminance is the target luminance (W luminance value L_{W} determined by step S4 of FIG. 9) when only W is displayed.

It is noted that the RGBW signal value in order to realize the target white Wₜ (255) when the R, G, and B input signal values are all 255 is previously calculated based on the luminance value L_{R} (which corresponds to the above LR1), the L_{G} (which corresponds to the above LG1), the L_{B} (which corresponds to the above LB1), the luminance value L_{R} calculated by the above step S4 (which corresponds to the above LR2), the L_{G} (which corresponds to the above LG2), the L_{B} (which corresponds to the above LB2), and the L_{W} (which corresponds to the above LW2) that are calculated by sep S3 of the panel adjustment processing.

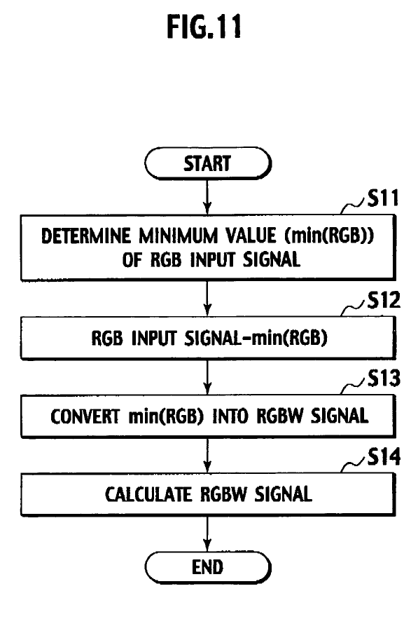

FIG. 11 shows a procedure of a signal conversion processing for converting an RGB input signal to an RGBW signal.

First, the minimum value (min(RGB)) of an RGB input signal is determined (step S11). The example of FIG. 3 shows the min(RGB)=100.

Next, the min(RGB) is deducted from the respective R, G, and B input signals (step S12). The example of FIG. 3 shows the deduction results for R, G, and B are 100, 0, and 70 as shown in FIG. 5, respectively.

Next, by using the RGBW signal value in order to represent the target white Wₜ(255) when the R, G, and B input signal values are all 255, the min(RGB) is converted to an RGBW signal (step S13) When assuming that an RGBW signal value in order to represent the target white Wₜ(255) is a signal value as shown in FIG. 6, the RGBW signal corresponding to the min(RGB) in the example of FIG. 3 is a signal value as shown in FIG. 7.

Next, an RGBW signal corresponding to the RGB input signal is calculated by adding the deduction value calculated by the above step S12 {RGB-mnin(RGB)} with the signal value of the RGBW signal calculated by the above step S13 (step S14). In the example of FIG. 3, an RGBW signal corresponding to the RGB input signal is as shown in FIG. 8.

[4] Second RGB-RGBW Signal Conversion Processing

Wben the chromaticity of the target white can be represented by only the three colors of R, B, and W and when the minimum value of the RGB input signal is a G signal, then the processings of step S11 to step S14 of FIG. 11 (RGB-RGBW conversion routine) are used to obtain an RGBW signal in which one signal of R, G, and B signals (G signal) is zero.

When the chromaticity of the target white can be represented by only the three colors of R, B, and W and when the minimum value of the RGB input signal is a B signal, the processings of step S11 to step S14 of FIG. 11 (RGB-RGBW conversion routine) are also used to obtain an RGBW signal in which one signal of R, G, and B signals (B signal) is zero. When the chromaticity of the target white can be represented by only the three colors of G, B, and W and when the minimum value of the RGB input signal is an R signal, the processings of step S11 to step S14 of FIG. 11 (RGB-RGBW conversion routine) are also used to obtain an RGBW signal in which one signal of R, G, and B signals (R signal) is zero.

However, when the chromaticity of the target white can be represented by only the three colors of R, B, and W and when the minimum value of the RGB input signal is a color signal other than the G signal or when the chromaticity of the target white can be represented by only the three colors of R, B, and W and when the minimum value of the RGB input signal is a color signal other tan the B signal, or when the chromaticity of the target white can be represented by only the three colors of G, B, and W and when the minimum value of the RGB input signal is a color signal other than the R signal, one execution of the processings of step S11 to step S14 of FIG. 11 (RGB-RGBW conversion routine) does not allow one signal in an RGB signal in an obtained RGBW signal to be not zero.

Specifically, some conditions prevent, when the RGB-RGBW conversion routine is performed only onc time, one signal in an RGB signal in an obtained RGBW signal from being zero.

When an RGB input signal is converted to an RGBW signal so that one signal in the RGB signal in the RGBW signal is zero, a W signal has a larger value to increase the emission efficiency, thus providing lower power consumption.

Thus, the second RGB-RGBW signal conversion processing suggests a signal conversion method by which, regardless of conditions, an RGBW signal can be obtained in which one signal in an RGB signal is zero.

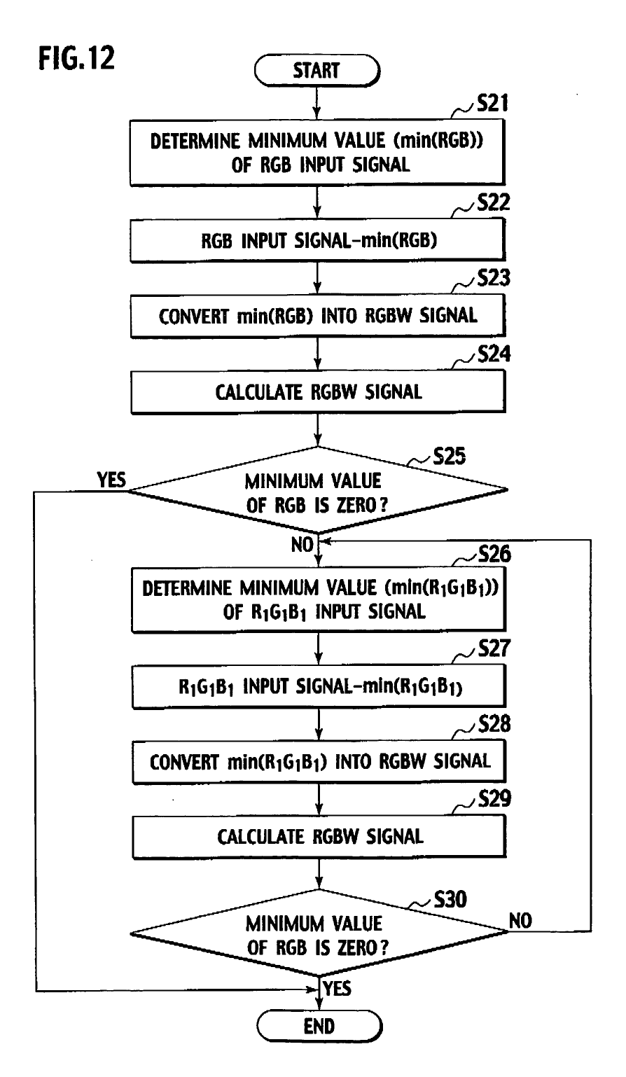

FIG. 12 shows a procedure of the second RGB-RGBW signal conversion processing for converting an RGB input signal to an RGBW signal.

It is assumed that an RGBW signal value in order to represent a target white Wₜ(255) when R, G, and B input signal values are all 255 is a signal value as shown in FIG. 6.

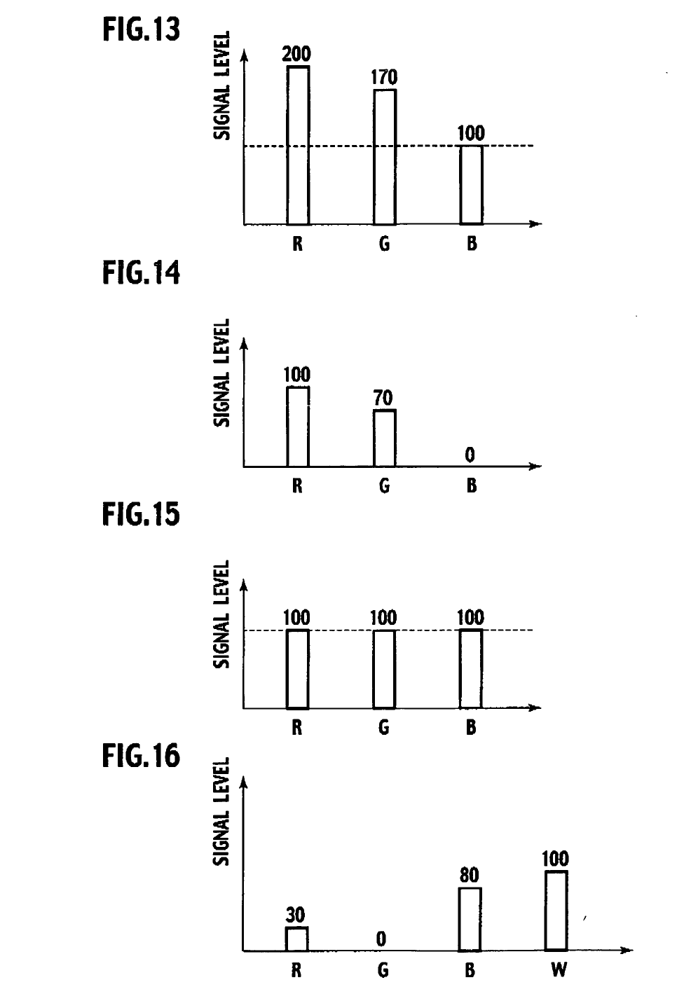

First, the minimum value (min(RGB)) in an RGB input signal is determined (step S21). When an RGB input signal value is R=200, G=170, and B=100 as shown in FIG. 13, then the min(RGB)=100 is established.

Next, the min(RGB) is deducted from the respective R, G, and B input signals (step S22). In the example of FIG. 13, the deduction results for R, G, and B are, as shown in FIG. 14, 100, 70, and G, respectively. Specifically, the RGB input signal is separated to the RGB signal value of FIG. 14 and the RGB signal value of FIG. 15.

Next, the min(RGB) is converted to an RGBW signal using an RGBW signal value in order to represent target white Wₜ(255) when R, G, and B input signal values are all 255 (step S23). When assuming that an RGBW signal value for realizing the target white Wₜ(255) is a signal value as shown in FIG. 6, an RGBW signal corresponding to the min(RGB) in the example of FIG. 13 is the one as shown in FIG. 16 (which is identical with FIG. 7).

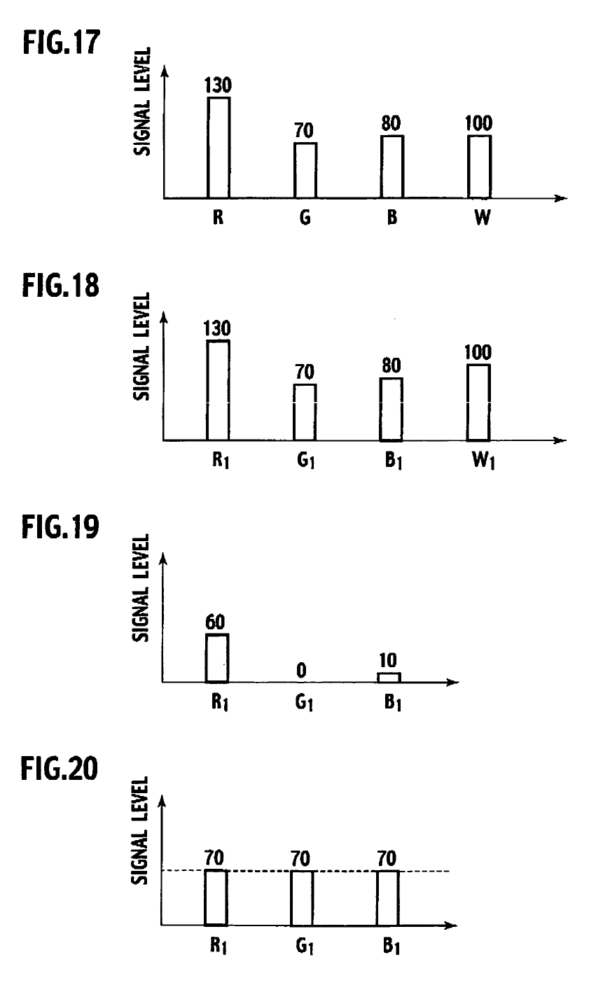

Next, by adding the deduction value {RGB-min(RGB)} calculated by the above step S22 to the signal value of the RGBW signal calculated by the above step S23, an RGBW signal corresponding to the RGB input signal is calculated (step S24). In the example of FIG. 13, an RGBW signal corresponding to the RGB input signal is as shown in FIG. 17.

In FIG. 17, the values of RGB, and W are calculated by the following formula (5).
R=100+30=130
G=70+0=70
B=0−80=80
W=0+100=100 (5)

Next, whether the minimum value of the RGB signal in the obtained RGBW signal is zero or not is determined (step S25). When the minimum value of the RGB signal in the obtained RGBW signal is zero, then the signal conversion processing is completed. Specifically, the RGBW signal obtained by the above step S24 is an RGBW output signal.

When the minimum value of the RGB signal in the obtained RGBW signal is not zero, then the obtained RGBW signal is recognized as an input RGBW signal and the same processings as those performed by the above steps S21 to S24 (RGB-RGBW conversion routine) are performed again.

Specifically, when the minimum value of the RGB signal in the obtained RGBW signal is not zero, then the obtained RGBW signal is assumed as an R₁G₁B₁W₁ input signal as shown in FIG. 18. Ihen, the minimurn value in the R₁G₁B₁W₁ input signal. (min(R₁G₁B₁)) is determined (step S26). In the casc where the R₁G₁B₁W₁ input signal is R=130, G=70, B=80, and W=100 as shown in FIG. 18, then the min(R₁G₁B₁)=70 is established as shown in FIG. 20.

Next, the min(R₁G₁B₁) is deducted from the respective R₁, C₁, and B₁ input signals (step S27). In the example of FIG. 18, the deduction results to R, G, and B are, as shown in FIG. 19, 60,0, and 10, respectively Specifically, the R₁, C₁, and B₁ input signals are separated to R₁, G₁, and B₁ signal values of FIG. 19 and R₁, G₁, and B₁ signal values of FIG. 20.

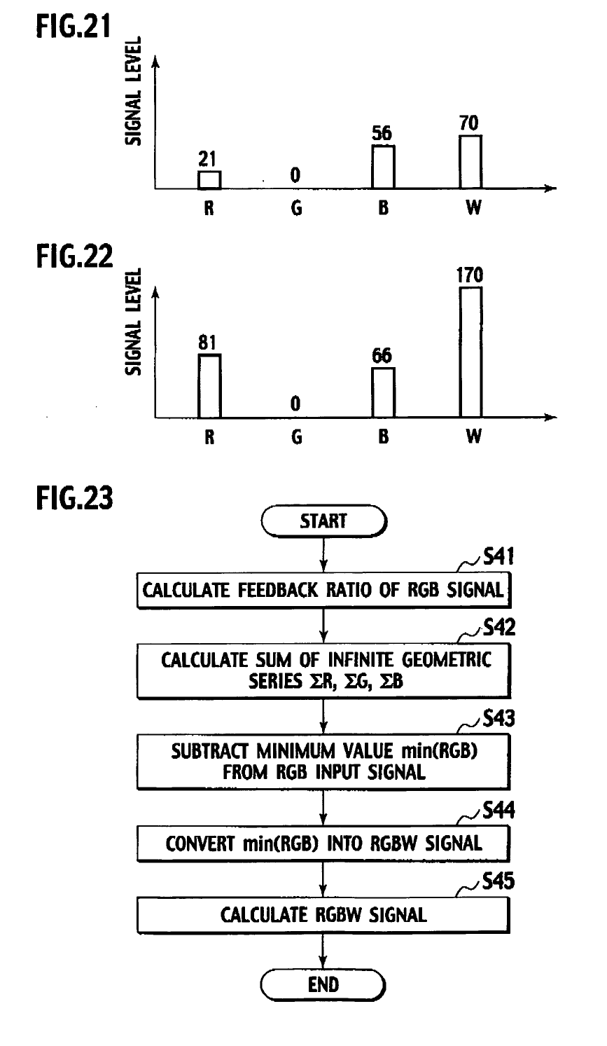

Next, the min(R₁G₁B₁) is converted to an RGBW signal using an RGBW signal value for representing the taget white Wₜ(255) for which R, G, and B input signal values are all 255 (step S28). When the RGBW signal value for realizing the target white Wₜ (255) is a signal value as shown in FIG. 6, then the RGBW signal corresponding to the min(R₁G₁B₁) in the example of FIG. 20 has a signal value as shown in FIG. 21.

The RGB, and W values of FIG. 21 are calculated by the following formula (6).
R=77×70/255=21
C=0×70/255=0
B=204×70/255=56
W=255×70/255=70 (6)

Next, by adding, to the deduction value {R₁G₁B₁-min(R₁G₁B₁)} calculated by the above step S27, the RGB signal value in the RGBW signal calculated by the above step S28 and by adding, to the W₁ in the R₁G₁B₁W₁ input signal, the W signal value in the RGBW signal calculated by the above step S28, a W signal is calculated (step S29). This provides the RGBW signal.

The above example shows the RGBW signal as shown in FIG. 22. The RGB, and W values of FIG. 22 are calculated by the following formula (7).
R=60+21=81
G=0+0=0
B=10+56=66
W=100+70=170 (7)

Next, whether the minimum value of the RGB signal in the RGBW signal calculated by the above stcp S29 is zero or not is determined (step S30). When the minimum value of the RGB signal in the resultant RGBW signal is zero, then the signal conversion processing is converted.

When the minirnum value of the RGB signal in the resultant RGBW signal is not zero, then the processing returns to the above step S26. Specifically, an RGB-RGBW conversion routine is repeatedly performed until the minimum value of the RGB signal in the resultant RGBW signal is zero.

[5] Third RGB-RGBW Signal Conversion Processing

As described in the above first RGB-RGBW signal conversion processing, some conditions may cause a signal having zero by deducting the min(RGB) to have a value equal to or higher than one by the subsequent conversion from the min(RGB) to an RGBW signal. In such a case, the RGB-RGBW conversion routine is repeatedly performed as described in the above second RGB-RGBW signal conversion processing.

The third RGB-RC:BW signal conversion processing suggests a signal conversion method by which one RGB-RGBW conversion routine is performed to provide an RGBW signal in which at least one of R, G, and B signals is zero.

This exemplary embodiment focuses attention on one signal of R, G, and B signals and will describe the signal conversion process. When assuming that the signal for which attention is being paid is always handled as the min(RGB) and the conversion of the min(RGD) to an RGBW signal allows about 80% of the converted W signal to be fed back to the signal, then the signal for which attention is being paid changes, as shown in the following formula (8), depending on the number at which the RGB-RGBW conversion routine is performed when an initial value is 50 for instance.
50→40→32→25.6→20.5→16.4→13.1 . . . →0 (8)

In this case, the W signal has a value obtained by adding all values in the above formula (8) and can be calculated as the sum of an infinite geometric progression having a first term of 50 and a common ratio of 0.8. When −1<common ratio<1 is established, then the sum of the Infinite geometric progression can be simplified to be the following formula (9).
Sum of infinite geometric progression=first term/(1−common ratio) (9)
Thus, when the infinite geometric progression is represented by the above formula (8), the sum of the infinite geometric progression will be: 50/(1-0.8)=250.

In an actual system, the sum of the infinite geometric progression as described above is calculated for the respective R, G, and B signals to perform one RGB-RGBW conversion routine while assuming that the minimum one of them is the min(RGB). As a result, one of R, G, and B signals of the resultant RGBW signal is 0(zero) and the other two have values equal to or higher than zero.

The following section will describe an example in which R, G, and B input signal values are R=255, G=255, and B=50.

When assuming that the RGBW signal for representing the target white Wₜ (255) in the case where R, G, and B input signal values are all 255 has signal values as shown in FIG. 6, then a feedback ratio of an RGB signal by the conversion of the min(RGB) to the RGBW signal is 0.3 (=R of FIG. 6/W=77/255 of FIG. 6), 0 (=G of FIG. 6/W of FIG. 6), and 0.8 (=B of FIG. 6/W=204/255 of FIG. 6).

When assuming that the sum of the infinite geometric progression corresponding to R, G, and B is ΣR, ΣG, and ΣB, then ΣR, ΣG, and ΣB are as shown in the following formula (10).
ΣR=255/(1−0.3)=364
ΣG=255/(1−0)=255
ΣB=50/(1−0.8)=250 (10)

Since the minimum value is 250, deduction of 250 from the RGB input signal value provides a deduction result as shown in the following formula (11).
R=255−250=5
G=255−250=5
B=50−250=−200 (11)

When the min(RGB)(=250) is converted to an RGBW signal on the other band, the conversion result is as shown in the following formula (12).
R=250×0.3=75
G=250×0=0
B=250×0.8=200
W=250 (12)

Thus, the RGBW output signal is as shown in the following formula (13).
R=5+75=80
G=5+0=5
B=200+200=0
W=250 (13)

FIG. 23 shows a procedure of the third RGB-RGBW signal conversion processing for converting an RGB input signal to an RGBW signal.

A feedback ratio of an RGB signal is calculated by an RGBW signal value for representing a target white Wₜ (255) when R, G, and B input signal values are all 255 (step S41). When assuming that the RGBW signal value for representing the target white Wₜ(255) has a signal value as shown in FIG. 6, then the feedback ratio of the RGB signal is 0.3(=77/255), 0, and 0.8(=204/255).

Next, with regards to the respective R, G, and B input signals, the sum of the infinite geometric progression of ΣR, ΣG, and ΣB is calculated in which the R, G, and B input signals are in the first term and the feedback ratio calculated by the above step S41 is the common ratio (step S42).

Next, the minimum value of the sam of the infinite geometric progression of ΣR, ΣG, and ΣB calculated for the respective R, G, and B input signals is deducted, as the min(RGB), from the RGB input signal (step S43).

Next, the min(RGB) is converted to an RGBW signal using an RGBW signal value for representing the target white Wₜ(255) when R, G, and B input signal values are all 255 (step S44).

Next, by adding, to the deduction value {RGB-min(RGB)} calculated by the above step S43, the RGBW signal calculated by the above step S44, an RGBW signal corresponding to the RGB input signal is calculated (step S45).

### First Embodiment

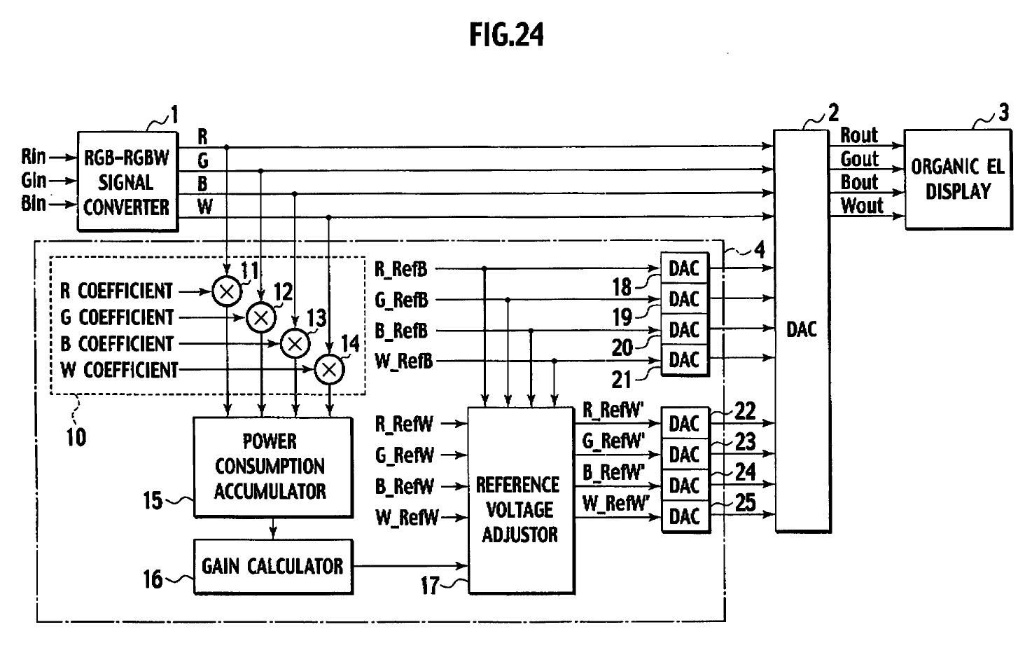

An arrangement of a display apparatus according to a first embodiment of the present invention will be described in detail below. FIG. 24 shows an arrangement of a display apparatus including an RGBW type organic EL display.

The display apparatus includes: an RGB-RGBW signal converter 1 for converting digital RGB input signals Rin, Gin, and Bin to digital RGBW input signals R, G, B, and W; a digital to analog converter (DAC) 2 for converting the RGBW input signals R, G, B, and W obtained by the RGB-RGBW signal converter 1 into analog RGBW output signals Rout, Gout, Bout, and Wout; an RGBW type organic EL display 3 for receiving the RGBW output signals Rout, Gout, Bout, and Wout obtained by the DAC 2; and a reference voltage controller 4 for controlling the reference voltage set in the DAC 2.

The RGB-RGBW signal converter 1 is the one as shown in FIG. 23 for example that uses the same processing as the third RGBB-RGBW conversion processing to convert an RGB signal to an RGBW signal.

The reference voltage controller 4 receives the digital RGBW input signals R, G, B, and W supplied from the RGB-RGBW signal converter 1. The reference voltage controller 4 controls the reference voltage set in the DAC 2 based on the digital RGBW input signals X, C, B, and W supplied from the RGB-RGBW signal converter 1.

The reference voltage set in the DAC 2 includes, with regards to the respective R, G, B, and W, black-sidc reference voltages R_RefB, G_RefB, B_RefB, and W_RefB (which will be collectively referred to as RefB) and whiteside reference voltages R_RefW, G_RefW, B_RefW, and W_RefW (which will be collectively referred to as RefW).

The black-side reference voltage RefB is a reference voltage for defining an emission luminance to the black level of an input signal and is fixed in the first embodiment. The white-side reference voltage RefW is a reference voltage for defining an emission luminance to the white level of an input signal and is controlled by the reference voltage controller 4 in the first embodiment.

The DAC 2 converts, based on an input-output characteristic defined by the black-side reference voltage RefB and the white-side reference voltage RefW′ supplied from the reference voltage controller 4, digital RGBW input signals R, G, B, and W to analog RGBW output signals Rout, Gout, Bout, and Wout. The analog RGBW output signals Rout, Gout, Bout, and Wout obtained by the DAC 2 are supplied to the RGBW type organic EL display 3.

The reference voltage controller 4 includes: an input signal/current consumption converter 10 for converting the RGBW input signals R, G, B, and W to current consumption values; an power consumption accumulator 15; a gain calculator 16; a reference voltage adjustor 17; and a plurality of DACs 18 to 25.

The input signal/current consumption converter 10 includes four multipliers 11 to 14. The multiplier 11 multiplies a digital input signal R with a coefficient K_{R} for each one unit pixel. The multiplier 12 multiplies a digital input signal G with a coefficient K_{G} for each one unit pixel. The multiplier 13 multiplies a digital input signal B with a coeflicient K_{B} for each one unit pixel. The multiplier 14 multiplies a digital input signal W with a coefficient K_{W} for each one unit pixel. The coefficients K_{R}, K_{G}, K_{B}, and K_{W} are set to have values in accordance with the current consumption when R, G, B, and W unit pixels are used for a unicolor display.

The coefficients K_{R}, K_{G}, K_{R}, and K_{W} are previously calculated in the manner as described below. After the adjustment of white balance, the organic EL display 3 is allowed to perform a unicolor display for each of R, G, B, and W unit pixels of the organic EL display 3. The unicolor display is performed while the maximum input tone being set. Then, the current consumption of the organic EL display 3 during the unicolor display is measured for each color. The measured current values are as shown in Table 1 for instance.

TABLE 1

| | Current Consumption [mA] | Coefficient |
|---|---|---|
| R unicolor display | 60 | K_{R} = 0.86 |
| G unicolor display | 55 | K_{G} = 0.79 |
| B unicolor display | 70 | K_{B} = 1.00 |
| W unicolor display | 50 | K_{W} = 0.71 |

Based on the maximum value of the current measurement value as a reference value, a ratio of the current measurement value of each color to the reference value is calculated and the resultant ratio is used as a coefficient corresponding to the color. The example of Table 1 shows a reference value of 70. Thus, the coefficient K_{R} corresponding to R is 60/70=0.86, the coefficient K_{G} corresponding to G is 55/70=0.79, the coefficient K_{B} corresponding to B is 70/70=1.00, and the coeflicient K_{W} corresponding to W is 50/70=0.71.

The power consumption accumulator 15 calculates, for each one frame, the total sum of accumulation values for one frame of the multiplication result of the respective multipliers 11, 12, 13, and 14 or the accumulation value for one frame of the total sum of the multiplication result of the respective multipliers 11, 12, 13, and 14 for each one pixel as an accumulated power consumption value on the basis of one frame. The gain calculator 16 calculates, in accordance with the magnitude of the accumulated power consumption value for each one frame obtained by the power consumption accumulator 15, the gain value for controlling the white-side reference voltage RefW.

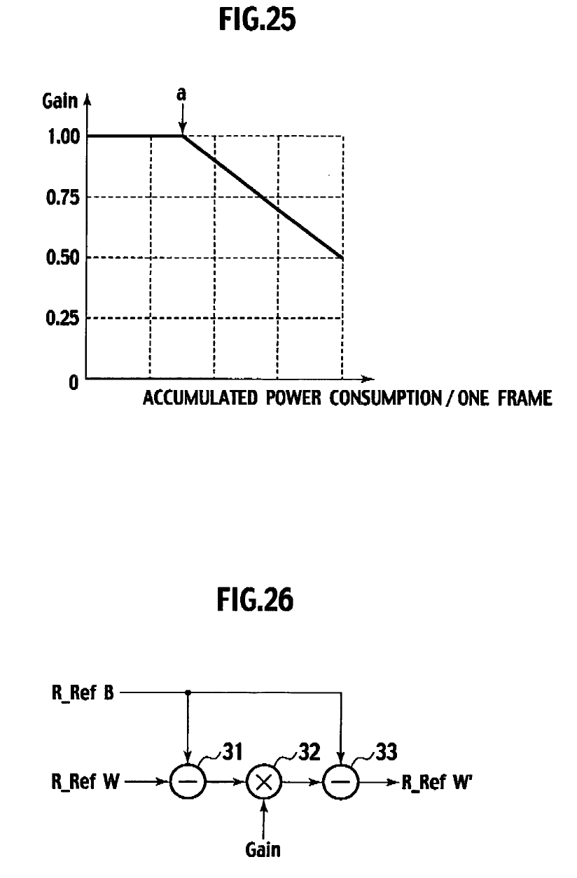

FIG. 25 shows an example of the input/output characteristic of the gain calculator 16 (i.e., the characteristic of the gain to the accumulated power consumption value on the basis of one frame). In this example, the gain is 1.00 when ihe accumulated power consumption value on the basis of one frame is “0” to “a,” and the gain value gradually decreases when the accumulated power consumption value on the basis of one fame exceeds “a”.

The reference voltage adjustor 17 generates adjusted white-side reference voltages R_RefW′, G_RefW′, B_RefW′, and W_RefW′ for the respective R, G, B based on: black-side reference voltages (hereinafter referred to as “black-side reference voltage”) previously set for the respective R, G, B, and W (R_RefB, G_RefB, B_RefB, W_RefB); white-side reference voltages previously set for the respective R, G, B, and W (hereinafter referred to as “white-side reference voltage”) (R_RefW, G_RefW, B_RefW, W_RefW); and the gain value calculated by the gain calculator 16.

The respective black-side reference voltages R_RefB, G_RefB, B_RefB, and W_RefB the respective white-side reference voltages R_RefW, G_Ref, B_RefW, and W_RefW are given as a digital signal.

The reference voltage adjustor 17 includes reference voltage adjustors for the respective R, G, B, and W that have the same arrangement Thus, a reference voltage adjustor for R will be described.

FIG. 26 shows the reference voltage adjustment circuit for R.

The reference voltage adjustor includes a subtractor 31, a multiplier 32, and a subtractor 33.

The subtractor 31 calculates a difference (R_RefB-R_RefW) between the black-side reference voltage R_RefB to R and the white-side reference voltage R_RefW to R. The multiplier32 multiplies the output (R_RefB-R_RefW) of the subtractor 31 with the gain value. The subtractor 33 subtracts, from the black-side reference voltage R_RefB, the output (Gain×(R_RefB-R_RefW)) of the multiplier 32 to calculate the adjusted white-side reference voltage R_RefW′.

When the gain value is 1.00, the adjusted white-side reference voltage R _RefW′ equals to the white-side reference voltage R_RefW. The smaller the gain value is (i.e., the larger accumulated power consumption value on the basis of one frame is), the adjusted white-side reference voltage R_RefW′ increases toward the black-side reference voltage R_RefB. Specifically, the larger the accumulated power consumption value on the basis of one frame is, the emission luminance of the organic EL element (driving current) to a white level of the input signal decreases.

The respective black-side reference voltages R_RefB, G_RefB, B_RefB, and W_RefB are converted, by DACs 18, 19, 20, and 21, to analog signals and are supplied to the DAC 2. The respective adjusted white-side reference voltages R _RefW′, G_RefW, B_RefW′, and W_RefW′ are converted, by DACs 22, 23, 24, and 25, to analog signals and are supplied to the DAC 2.

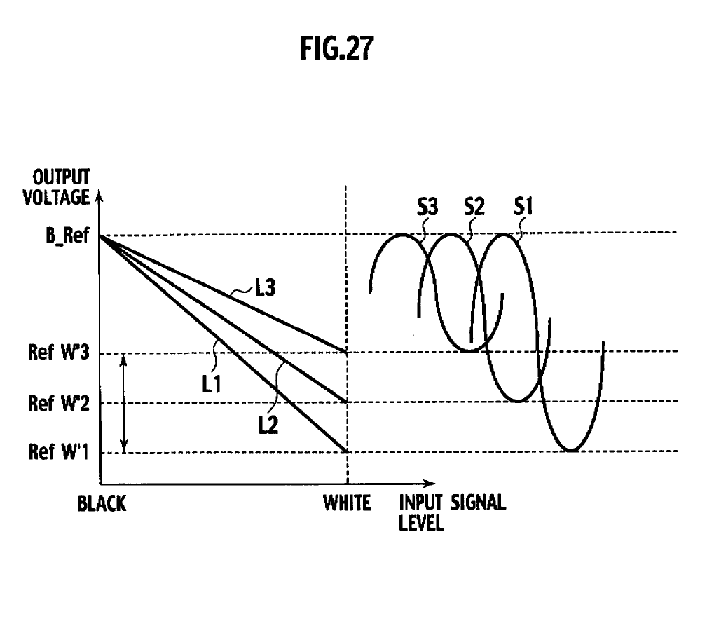

FIG. 27 shows the input-output characteristic of the DAC 2.

In FIG. 27, RefW′1 denotes a white-side reference voltage (=white-side reference voltage RefW) supplied to the DAC 2 when a accumulated power consumption value on the basis of one frame is small, RefW′3 denotes a white-side reference voltage supplied to the DAC 2 when a accumulated power consumption value on the basis of one frame is large, and RefW′2 denotes a white-side reference voltage supplied to the DAC 2 when a accumulated power consumption value on the basis of one frame is an intermediate value.

When the white-side reference voltage supplied to the DAC 2 is RefW′1, then the DAC 2 has an input-output characteristic shown by a straight line L1. In this case, when an input signal changing from a black level to a white level is inputted to the DAC 2 in a cyclical manner, then an output waveform as shown by a curve S1 is obtained.

When the whiteside reference voltage supplied to the DAC 2 is RefW′3, the DAC 2 has an input-utput characteristic as shown by a sight line L3. In this case, when an input signal changing from a black level to a white level is inputted to the DAC 2 in a cyclical manner, then the output waveform as shown by a curve S3 is obtained.

When the white-side reference voltage supplied to the DAC 2 is RefW′2, the DAC 2 has an input-output characteristic as shown by a straight line L2. In this case, when an input signal changing from a black level to a white level is inputted to the DAC 2 in a cyclical manner, an output waveform as shown by a curvc S2 is obtained.

Specifically, it is understood that, by controlling a white-side reference voltage in accordance with an accumulated power consumption value on the basis of one frame, the amplitude of the output signal of thc DAC 2 is controlled.

### Other Embodiments

Various modifications will become possible for those skilled in the art after receiving the teachings of the present disclosure without departing from the scope thereof.

Although the above section has described, in the respective exemplary embodiments, the display apparatus including an RGBW-type self light-emitting display, this invention also can be applied to a display apparatus including an RGBX-type self lightemitting display (X is an arbitrary color other than R, G, and B).

What is claimed is:

1. A display apparatus comprising:
an RGB-RGBX signal converter configured to convert digital R, G, and B input signals into digital R, G, B, and X input signals, X refers to an arbitrary color other than R, G, and B;
a D/A converter configured to convert the digital R, G, B, and X input signals into analog R, G, B, and X output signals;
an RGBX type self light-emitting display configured to receive the analog R, G, B, and X output signals;
a calculator configured to calculate an accumulated power consumption value of the self lightemitting display for each screen, based on the digital R, G, B, and X input signals; and
a controller configured to control amplitudes of the respective analog R, G, B, and X input signals by controlling a reference voltage supplied to the D/A converter based on the accumulated power consumption value, and to supply the respective amplitude-controlled analog R, G, B, and X input signals to the self light-emitting display.

2. The display apparatus of claim 1, wherein the calculator comprises:
a plurality of multipliers that are provided for the respective digital R, G, B, and X input signals and that multiply, for each one pixel, the respective digital R, G, B, and X input signals with a coefficient depending on current consumption for unicolor display by respective R, G, B, and X unit pixels; and
a power consumption accwnulator configured to calculate, for each one screen, a total sum of accumulation values for one screen of the multiplication result of the respective multipliers or an accumulation value for one screen of the total sum for each one pixel of the multiplication result of the respective multipliers as the accumulated power consumption value.

3. The display apparatus of claim 1, wherein the controller controls the reference voltage so that the respective analog R, G, B, and X input signals become small amplitudes when the accumulated power consumption value is higher than a fixed value.

4. The display apparatus of claim 1, wherein:
the reference voltage includes a black-side reference voltage for defining emission luminances to black levels of the respective digital R, G, B, and X input signals and a white-side reference voltage for defining emission luminances to white levels of the respective R, G, B, and X input signals; and
the controller controls the white-side reference voltage based on the accumulated power consumption value.
